(19) United States
(12) Patent Application Publication
(10) Pub. No.: US 2025/0388414 A1
(43) Pub. Date: Dec. 25, 2025

(54) SUBSTRATE HANDLING DEVICE AND END EFFECTOR

(71) Applicant: ASM IP Holding B.V., Almere (NL)

(72) Inventors: Kyle Tantiwong, Scottsdale, AZ (US); Samer Banna, Phoenix, AZ (US); Dongyang Chen, Chandler, AZ (US); Mario Gonzalez, Phoenix, AZ (US)

(21) Appl. No.: 19/246,841

(22) Filed: Jun. 24, 2025

Related U.S. Application Data
(60) Provisional application No. 63/663,333, filed on Jun. 24, 2024.

(51) Int. Cl. B65G 47/90

(52) U.S. Cl. CPC B65G 47/90

(57) ABSTRACT

An end effector for a substrate handling device suitable for a semiconductor fabrication tool. The end effector is adapted to support the substrate and is connectable to a robotic arm. The end effector includes: (a) a body having a top surface and a bottom surface; and (b) at least one supporting projection protruding from the top surface of the body for contacting and supporting the substrate. The supporting projection is provided with a diamond-like carbon coating.

### CROSS-REFERENCE TO RELATED APPLICATION(S)

This Application claims the benefit of U.S. Provisional Application 63/663,333 filed on Jun. 24, 2024, the entire contents of which are incorporated herein by reference.

### FIELD OF INVENTION

The present invention relates to the field of devices and methods for handling semiconductor substrates.

More specifically, the present invention relates to the field of robotic end effectors for handling semiconductor substrates, where the end effectors are provided with wear-resistant coatings.

Furthermore, the present invention relates to the field of automated substrate handling platforms and semiconductor fabrication tools implementing such automated substrate handling platforms.

### BACKGROUND OF THE DISCLOSURE

A typical semiconductor fabrication tool is a complex machine that generally comprises two main components: (i) an automated substrate handler platform, and (ii) one or more process modules (PMs).

The PMs are generally used to grow or deposit films of semiconductor materials on a substrate and may include one or more reaction chambers.

The automated substrate handler platform may comprise one or more of the following: (a) a substrate carrier, used to store and transport substrates during the manufacturing process; (b) a substrate aligner to properly orientate the substrate before it is processed; and (c) one or more substrate handling robots, to transport the substrate between the substrate carriers and the PMs.

The platform's main purpose is therefore to handle semiconductor substrates, transporting them between one or more substrate carriers and the PMs, via one or more substrate handling robots.

Substrate carriers, such as FOUPs (Front Opening Universal Pods), FOSB Box (Front Opening Shipping Box), SMIF Pods (Standard Mechanical Interface), or Open Cassettes are specialized carriers designed to hold substrates securely in a controlled environment, to allow transferring them between machines for processing or measurement.

The part of the substrate handling robot that physically interacts with the substrates, i.e., picks and displaces them, is called an end effector. For vacuum applications, end effectors typically rely on either gravity and friction or physical clamping to constrain the substrate.

In general, semiconductor processing is highly sensitive to even the smallest of particle contamination. The end effector can be a direct source of particles due to the fact it enters in direct physical contact with the substrate, for instance though pads or other suitably prepped contact points/areas. Thus, the end effector design and composition can dramatically impact the semiconductor fabrication tool performance, depending on the size and quantity of mechanical defects or physical scratches they may introduce.

Typically, the end effector performance degrades over time, due to use and wear, and eventually generates particles in the tool, thus affecting substrate quality.

Therefore, for most applications in the semiconductor industry, end effectors are maintenance items with a limited lifetime.

A few different approaches have been used to address this problem.

For particle control, it is possible to use single piece machined specialty materials with very highly prepped contact points. Depending on the process temperatures of the PMs, end effectors may be made of quartz or ceramic materials, which are costly to machine. These single piece end effectors degrade with time, and must be replaced at regular intervals, thus representing a reoccurring cost of ownership for chip manufacturers.

An alternative solution is to employ a two-piece construction end effector, where the substrate contact pads are removable pieces. In these cases, the pads are typically dissimilar materials from the rest of the end effector body. During high temperature processes, the multi-piece construction represents a particle generation source, together with the potential mismatch of the thermal expansion coefficient of the different materials.

Thus, while composite material designs offer improved lifetime, they typically underperform in respect to particle generation.

In conclusion, none of the current approaches is suited to simultaneously address both particle performance and lifetime of the end effector.

Additionally, in some semiconductor fabrication tools, such as, for example, Atomic Layer Deposition (ALD) and Epitaxial tools for the deposition of Si and/or Si compounds (such as SiGe, SiP, SiN, SiO), metal oxides and nitrides, and/or molybdenum oxides and nitrides, there is occasionally the need for the end effector to be able to operate under low vacuum (for instance at pressures below 1000, 500 or 100 mTorr) and at relatively high-temperatures (for instance between 200-700° C.).

In view of the above problems, it is therefore desirable to provide an end effector for transferring a substrate, such as a semiconductor substrate, where the substrate handling device exhibits improved lifetime and reduced particle generation.

It is further desirable to provide an end effector suitable to work at relatively high-temperature and/or under low vacuum.

It is further desirable to provide a substrate handling device implementing an end effector with improved lifetime and reduced particle generation, as well as an automated substrate handler platform and a semiconductor fabrication tool implementing said substrate handling device.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

It is an object of the invention to provide an end effector suitable for transferring a substrate, such as a semiconductor substrate, where the end effector exhibits improved lifetime and reduced particle generation.

It is a further object of the invention to provide an end effector suitable to transfer a substrate between process modules or between a process module and a carrier or other functional elements of a semiconductor fabrication tool, and optionally suitable to operate at a temperature of 200-700° C., preferably 300-600° C.

It is a further object of the invention to provide an end effector suitable to transfer a substrate at pressures below 1000 mTorr, and optionally below 500, and optionally below 100 m Torr.

It is a further object of the invention to provide a substrate handling device, an automated substrate handler platform and a semiconductor fabrication tool implementing the end effector according to the invention.

The main objectives hereinbefore described are achieved through the invention recited in the appended claims, which constitute an integral part of the present description.

It is noted that the use of reference signs in the claims does not limit their scope. The sole purpose of reference signs is to make the claims easier to understand in light of the figures.

### BRIEF DESCRIPTION OF THE FIGURES

The illustrations presented herein are not meant to be actual views of any particular material, structure, or device, but are merely idealized representations that are used to describe embodiments of the disclosure.

FIG. 1 is a plan view of a semiconductor fabrication tool according to the present invention.

FIG. 2 provides a plan view of an end effector according to an embodiment of the present invention.

FIG. 3 provides a side view of the end effector of FIG. 2.

FIG. 4 provides a plan view of an end effector according to an embodiment of the present invention.

FIG. 5 provides a side view of the end effector of FIG. 4.

FIG. 6 is a plan view of an end effector according to an embodiment of the present invention.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular embodiments described below.

Reference will now be made to the Figures wherein like reference numerals identify similar structural features or aspects of the subject disclosure.

It will be appreciated that elements in the figures are illustrated for simplicity and clarity. In particular some elements may have been omitted or may have not been drawn to scale. For example, the dimensions of some of the elements in the figures may be exaggerated relative to other elements to help improve understanding of illustrated embodiments of the present disclosure.

According to a first aspect, the present invention relates to an end effector 10 for a substrate handling device 4 suitable for transferring a substrate 5 within an automated substrate handler platform 3 of a semiconductor fabrication tool 1.

In particular, the end effector 10 is adapted to support the substrate 5 and is connectable to a robotic arm 9.

With the expression “adapted to support the substrate” it is meant that the end effector 10 is suitable to hold, grab, and/or transfer the substrate 5.

The end effector further comprises: (a) a body 11 having a top surface and a bottom surface; and (b) at least one supporting projection 12 protruding from the top surface of the body 11 for contacting and supporting the substrate 5.

Therefore, the top surface of the end effector is adapted to face and support the wafer via the supporting projections.

The end effector according to the invention is characterized in that at least one supporting projection 12 is provided with a diamond-like carbon (DLC) coating 13.

With the expression “provided with”, it is meant that the supporting projection is covered in toto or in part with a layer of diamond-like carbon material. It is preferable, however, that the area of the supporting projection configured to be in direct contact with the substrate is entirely coated with DLC.

DLC defines a class of amorphous carbon materials that typically contain a significant amount of sp³ hybridized carbon atoms. DLC is available in different forms, depending on whether the material features a predominance of sp³ or sp² carbon bonds, and if the material additionally includes fillers such as hydrogen and/or metals.

In general, DLC is a material that features diamond-like properties, in terms of hardness, temperature resistance, and tribological properties.

Hence, the end effector according to the invention is advantageously resistant to abrasive and adhesive wear due to contact pressure and sliding friction of the (DLC-coated) supporting projections with the substrate, during handling and transfer operations. This allows to increase the lifetime of the end effector without introducing a source of particle generation.

It is noted that DLC coatings may be obtained with several techniques, for instance chemical vapor deposition or physical vapor deposition processes from a variety of gaseous or solid carbon sources. The present invention is not limited by the specific coating techniques used.

The person with average skill in the art will be able to adapt the number and size of supporting projections to the dimensions and shape of the substrate, in order to ensure adequate support while preferably limiting the number of contact points. As a non-limiting example, a number of supporting projections ranging from 3 to 10 has been observed to work particularly well in the execution of the invention. In general, it is preferable to provide all supporting projections meant to contact the substrate with a DLC coating.

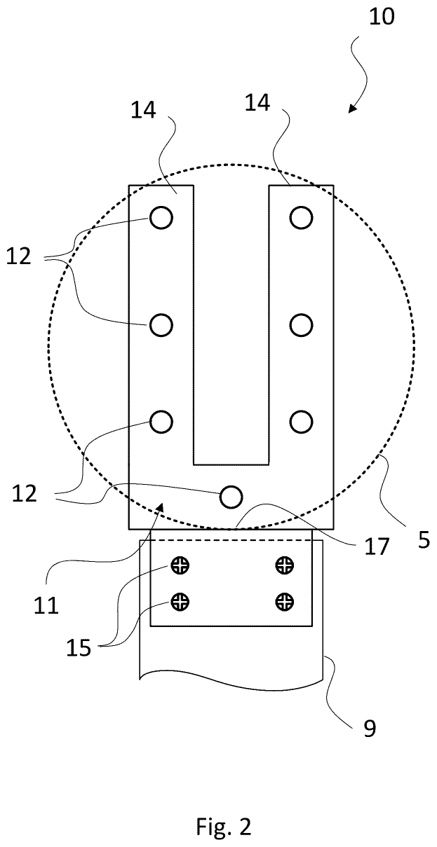

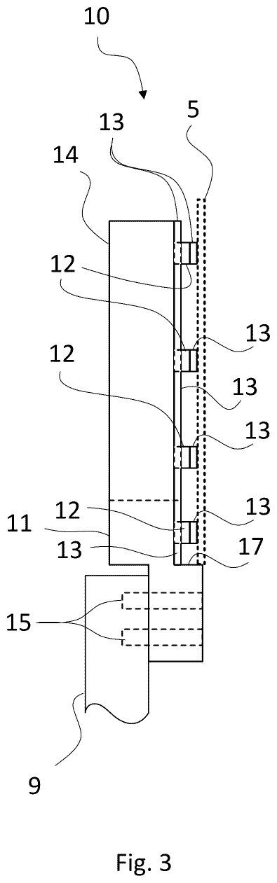

Under one embodiment, the top surface of the body of the end effector is also provided, in toto or in part, with a diamond-like carbon coating 13. An example of this embodiment is provided in FIG. 2 and FIG. 3.

Advantageously, the end effector 10 thus designed provides a resistant and uniform surface facing the substrate, as can be observed in FIG. 2 and FIG. 3, which ensures robustness of the device and minimizes the chance of particles reaching the substrate.

Under an embodiment, the end effector according to the present invention is characterized in that the body and the supporting projections are made in one piece. Advantageously, this allows to further reduce a possible source of particle generation.

Alternatively, the supporting projections may be removable from the body. This embodiment allows to replace the supporting projections when they eventually deteriorate, thus reducing maintenance costs.

It is understood that the body of the end effector and its supporting projections can be made of the same material or may be of different materials.

Preferably, the supporting projections and the body of the end effector are made of substantially the same material, to avoid particle generation due to potential mismatch of the thermal expansion coefficient of the body versus the supporting projections.

The body of the end effector may advantageously be made of materials exhibiting low heat conductivity, high stiffness to weight ratio, and a low thermal expansion coefficient.

Non-limiting examples of suitable materials include: metal matrix composites, quartz, carbon, aluminum (for example aluminum nitride), titanium, stainless steel, nickel-plated aluminum, or ceramics. These suitable materials may be used alone or in combination with other materials. These materials may be plated, doped, or used in alloys as applicable.

Under an embodiment, the body of the end effector is made of quartz or of a ceramic material, such as silicon carbide, zirconia, alumina and/or Ti-doped ceramics, for instance Ti-doped alumina. Advantageously, the end effector thus designed can be used at temperatures of 200-700° C.

Under an embodiment, the diamond-like carbon coating 13 is formed, i.e., comprises or consists, of tetrahedral hydrogen-free amorphous carbon (ta-C) and/or tetrahedral hydrogenated amorphous carbon (ta-C:H).

Advantageously, ta-C and ta-C:H are two forms of DLC characterized by a sp³ predominating C—C-bond type, which imparts the most diamond-like properties to the material in terms of hardness, wear resistance, and slickness, if compared to other forms of DLC.

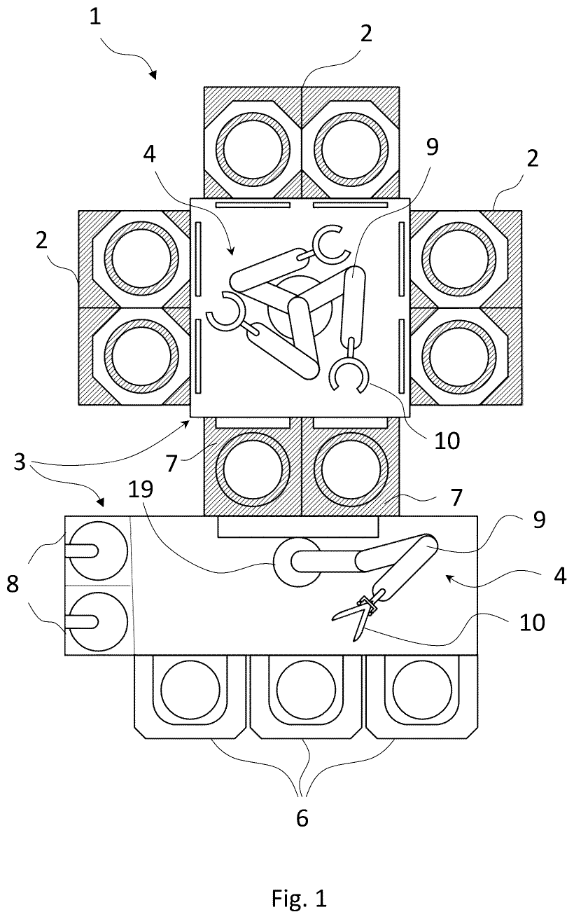

Under an embodiment, the body 11 of the end effector 10 comprises two or more protruding prongs 14. For example, the end effector may be substantially “Y” shaped, as depicted in FIGS. 1-6.

The body 11 of the end effector 10 may further comprise two or more distal posts 16 and a proximal member 17 raised with respect to the top surface of the body.

Each distal post 16 is positioned at a tip end of a protruding prong 14, and opposite to the proximal member 17, thereby forming a receptacle between each distal post 16 and the proximal member 17. The receptacle thus obtained is suitable to lodge a substrate 5.

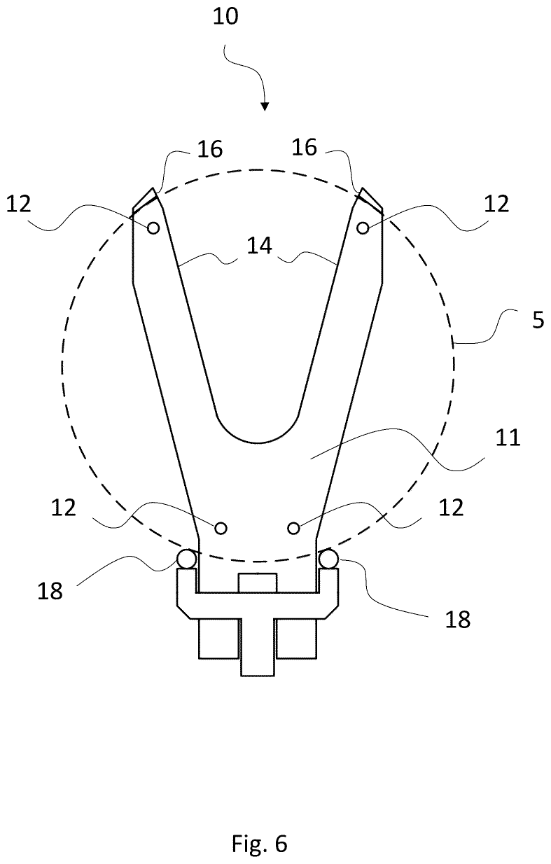

The proximal member is a raised element of the end effector, an “end stop” such as a wall (FIGS. 2-5), a clamp (FIG. 6), or a post, suitable to intercept a first (frontal) side of a substrate when the latter is introduced in the receptacle. The distal posts 16 are also raised elements of the end effector suitable to intercept a (back) side of a substrate, different from the first. The term side here refers to the lateral, peripheral side of the substrate. The terms “frontal” and “back” refer to the substrate orientation relative to the end effector.

It is noted that the receptacle is an empty space delimited, on the sides, by the distal posts and the proximal member, and, on the bottom, by the supporting projections (which advantageously protrude lower than both the distal posts and the proximal member). Typically, in each end effector, the shape and size of the receptacle is adapted for the substrate to be used.

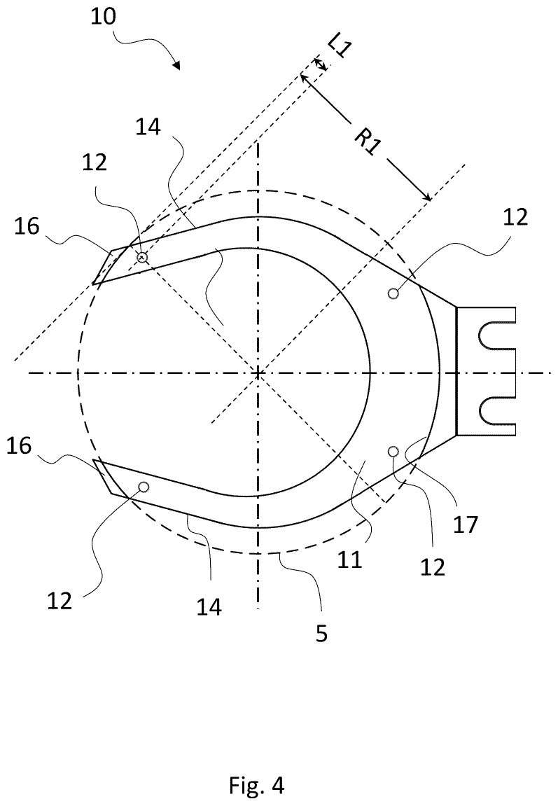

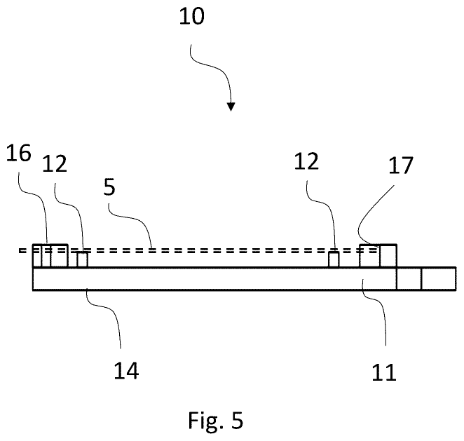

Under an embodiment, the two protruding prongs 14 of the end effector 10 are fixed or integral with the body 11. The end effector thus designed may be advantageously used within a back-end robot, i.e., in a substrate handling device 4 used for transferring substrates between one or more process modules 2 and one or more load-lock chambers 4 of a semiconductor tool 1. An example of the present embodiment is provided in FIG. 4 and FIG. 5.

Under another embodiment, each protruding prong 14 of the end effector 10 is adapted to move with respect to the proximal member 17. For instance, each protruding prong may slide towards the proximal member once a substrate is positioned in the receptacle, until it is securely set in place against the proximal member and the distal posts, or it may slide in the opposite direction to release it therefrom. It is convenient to minimize the extent of the relative movement of the protruding prong with respect to the proximal member, to minimize particle generation and frictional stress on the substrate. For instance, the allowable movement may be <4% of the linear dimensions of the substrate.

The end effector thus designed may be advantageously used in a front-end robot, i.e., in a substrate handling device 4 used for transferring substrates between one or more substrate carriers 6 and one or more load-lock chambers 4 of a semiconductor tool 1.

Under another embodiment, the proximal member is a clamping member 18.

The clamping member 18 may be particularly advantageous to use in the back-end robot design hereinbefore described.

This design may further advantageously incorporate at least 4 supporting projections 12: at least two positioned inboard of the distal post 16 and at least two positioned outboard of the clamping member 18.

The substrate 5 may slide over the supporting projections 12 under the push of the distal posts 16 towards the clamping member 18, when the protruding prongs 14 are set sliding along a plane substantially parallel to the substrate 5 main surface and towards the clamping member.

It is noted that in this design no ramps are used, thus avoiding scratching the bottom surface of the substrate.

An example of the above embodiment is provided in FIG. 6.

The end effector according to any of the embodiments hereinbefore described may be adapted to handle, support and transfer substrates of different shape and size.

However, in many semiconductor fabrication applications, the substrates are of circular shape, and each end effector is configured to support and transfer a circular substrate of pre-defined size. In particular, the receptacle is of size and shape adapted to the substrate to be used. Typically, the supporting projections are arranged on the body of the end effector in a way to lie towards the outmost border of the substrates to be used. However, such an arrangement may cause inline defects.

Under an embodiment, the distal posts 16 and the proximal member 17 of the end effector 10 are mutually arranged to inscribe a circle C of radius R1.

Each supporting projection 12 may be placed on the top surface of the body 11 in such a way as to be at a maximum radial distance L1≤93% R1 from the center of the circle C. Optionally, L1>30% R1. It is understood that the circle C mentioned herein is not an actual physical object and is referenced to define the geometrical relation between different elements of the end effector.

With the expression “maximum radial distance” it is meant the maximum distance of the supporting projection from the center of the circle C. Since the supporting projection may not be punctiform or feature central symmetry, L1 is the maximum distance of the area of the supporting projection contacting the substrate measured from the center of the circle C.

This embodiment advantageously removes the supporting projections from the periphery of the substrate. It may prevent the supporting projections from being scratched by backside deposition of processed substrates and reduces the chance of backside particles migrating to the frontside.

Preferably, if the end effector is designed for a circular substrate of radius Rs, R1 can be advantageously chosen to be between 1,5-2.5% larger than Rs.

It is noted that while the present invention is not limited to substrates of specific size, shape and composition, it has been observed to work particularly well with semiconductor substrates of circular shapes, and size of approximately 50, 75, 100, 125, 150 mm in radius (i.e., 100, 150, 200, 250 and/or 300 mm in diameter).

It is also noted that the end effector hereinbefore described can be used under low vacuum, such as at pressures below 1000 mTorr, below 500 mTorr, and/or below 100 m Torr.

It is also noted that the end effector according to the present invention may comprise other features other than those described, without departing from the scope of the invention.

For instance, the end effector may be equipped with sensors to detect the presence, position, and orientation of a substrate.

For instance, the end effector may be equipped with a clamping member, and the latter may include grooved rollers, cushions, stops, and fasteners.

For instance, the end effector may be equipped with a suction system adapted to keep hold of the substrate during transfer, in case the end effector is used at atmospheric pressure.

Under a second aspect, the present invention relates to a substrate handling device 4 for transferring a substrate 5, comprising: (i) at least one robotic arm 9; (ii) at least one end effector 10 according to any embodiments hereinbefore described; and (iii) a movement mechanism 19 connected to the at least one robotic arm 9 directly or via one or more auxiliary arms.

The end effector 10 is connected to the robotic arm 9 and may be positioned at a tip end thereof.

For example, the end effector 10 may be connected to the robotic arm 9 via fastening means 15, such as screws, rivets, or interlocking mechanisms.

The movement mechanism 19 is a mechanism suitable for rotating and/or reciprocating the robotic arm 9 between a first position and a second position.

The first and second position can be, for example, a retracted and an extended position.

The movement mechanism 19 may be a rotating mechanism, to reciprocate between an extended position and a retracted position.

The auxiliary arms may not be necessary depending on the configuration of the movement mechanism, and in any case the number of the auxiliary arms can vary. For example, the number of auxiliary arms per end effector may range between 0-6.

The substrate handling device 4 thus described may be used to transfer substrates in an automated substrate handler platform 3 of a semiconductor fabrication tool 1, advantageously reducing the cost of ownership and particle generation within the tool thanks to the features of the end effector hereinbefore described.

The substrate handling device 4 may be used as a front-end robot or a back-end robot, depending on its positioning within an automated substrate handler platform and/or the choice of end effector.

Under a second aspect, the present invention relates to an automated substrate handler platform 3 for handling a substrate 5, comprising: (i) at least one substrate handling device 4 described above; (ii) at least one substrate carrier 6, suitable to store one or more substrates 5; and (iii) at least one substrate aligner 8 for orienting the substrate 5.

The automated substrate handler platform 3 may be optionally enclosed by at least one chamber, connected to a degassing system suitable to bring said chamber to a pressure below 1000 mTorr, preferably below 500 mTorr, even more preferably below 100 mTorr.

In addition or in alternative to the degassing system, a gas purging system may be used.

Under a third aspect, the present invention relates to a semiconductor fabrication

tool 1 comprising: (i) at least one process module 2 for processing and/or measuring at least one substrate 5; and (ii) the automated substrate handler platform 3 hereinbefore described.

The automated substrate handler platform 3 is adapted to transfer one or more substrates between at least one substrate carrier 6 and one or more process modules 2.

For example, as depicted in FIG. 1, the automated substrate handler platform 3 of the semiconductor fabrication tool 1 comprises: (i) a first and a second substrate handling device 4, and (ii) at least one load-lock chamber 7.

The first substrate handling device 4 is a front-end robot, i.e., is adapted to transfer a substrate 5 between a substrate carrier 6 and a load-lock chamber 7. It may be advantageously equipped with the end effector of FIG. 6. In the exemplary embodiment of FIG. 1, the front-end robot is provided with a robotic arm 9 connected to the movement mechanism 19 via two auxiliary arms.

The second substrate handling device 4 is a back-end robot, i.e., is adapted to transfer a substrate 5 between at least one load-lock chamber 7 and a process module 2. It may be advantageously equipped with the end effector of FIG. 4 and FIG. 5. In the exemplary embodiment of FIG. 1, the front-end robot is provided with a robotic arm 9 connected to the movement mechanism via one auxiliary arm, and the substrate handling device 4 is equipped with three end effectors and is configured to handle up to three substrates at a time.

The semiconductor fabrication tool according to the present disclosure may be successfully employed for atomic layer or epitaxial deposition of Si and/or Si compounds (such as SiGe, SiP, SiN, SiO), metal oxides and nitrides, and/or molybdenum oxides and nitrides on substrates.

The subject matter of the present disclosure includes all novel and nonobvious combinations and sub-combinations of the various processes, systems, and configurations, and other features, functions, acts, and/or properties disclosed herein, as well as any and all equivalents thereof.

### LIST OF REFERENCES

1. Semiconductor fabrication tool
2. Process module
3. Automated substrate handler platform
4. Substrate handling device
5. Substrate
6. Substrate carriers
7. Load lock chamber
8. Aligner
9. Robotic arm
10. End Effector
11. Body
12. Supporting projection
13. Diamond-like carbon coating
14. Protruding prongs
15. Fastening means
16. Distal post
17. Proximal member
18. Clamping member
19. movement mechanism

1. An end effector for a substrate handling device suitable for transferring a substrate within a semiconductor fabrication tool,
wherein the end effector is adapted to support the substrate and is connectable to a robotic arm; the end effector further comprising:
a body having a top surface and a bottom surface; and
at least one supporting projection protruding from the top surface of the body for contacting and supporting the substrate,
wherein the at least one supporting projection is provided with a diamond-like carbon coating.

2. The end effector according to claim 1, wherein the top surface of the body is provided, in toto or in part, with a diamond-like carbon coating.

3. The end effector according to claim 1, wherein the body and the at least one supporting projection are made in one piece.

4. The end effector according to claim 1, wherein the at least one supporting projection is removable from the body.

5. The end effector according to claim 1, wherein the body comprises one of the following materials: quartz, ceramic, carbon, aluminum, stainless steel, titanium, or composites thereof.

6. The end effector according to claim 1, wherein the diamond-like carbon coating is formed of: tetrahedral hydrogen-free amorphous carbon, and/or tetrahedral hydrogenated amorphous carbon.

7. The end effector according to claim 1, wherein the body comprises two or more protruding prongs.

8. The end effector according to claim 7, wherein the body further comprises two or more distal posts and a proximal member raised with respect to the top surface of the body;
wherein each distal post is positioned at a tip end of each protruding prong; and opposite to the proximal member, thereby forming a receptacle suitable to lodge a substrate.

9. The end effector according to claim 7, wherein the two protruding prongs are fixed or integral with the body.

10. The end effector according to claim 8, wherein each protruding prong is adapted to move with respect to the proximal member to secure the substrate onto the end effector and/or to release it therefrom.

11. The end effector according to claim 8, wherein the proximal member is a clamping member.

12. The end effector according to claim 8, wherein the distal posts and the proximal member are mutually arranged so as to inscribe a circle C of radius R1, and wherein each supporting projection is placed on the top surface of the body so as to be at a maximum radial distance L1≤93% R1 from the center of the circle C.

13. A substrate handling device for transferring a substrate, comprising:
at least one robotic arm;
at least one end effector according to claim 1; and
a movement mechanism connected to the at least one robotic arm directly or via one or more auxiliary arms,
wherein the at least one end effector is connected to the at least one robotic arm and positioned at a tip end thereof, and the movement mechanism is suitable for rotating and/or reciprocating said at least one robotic arm between a first position and a second position different from the first position.

14. An automated substrate handler platform for handling a substrate comprising:
at least one substrate handling device according to claim 13; and
at least one substrate carrier, suitable to store one or more substrates; and
at least one substrate aligner.

15. A semiconductor fabrication tool comprising:
at least one process module for processing and/or measuring at least one substrate; and
the automated substrate handler platform according to claim 14,
wherein the automated substrate handler platform is adapted to transfer the at least one substrate between at least one substrate carrier and the at least one process module.

16. The semiconductor fabrication tool according to claim 15, wherein the automated substrate handler platform comprises a first and a second substrate handling device;
wherein the semiconductor fabrication tool further comprises at least one load-lock chamber;
wherein said first substrate handling device is adapted to transfer the at least one substrate between at least one substrate carrier and at least one load-lock chamber; and said second substrate handling device is adapted to transfer the at least one substrate between at least one load-lock chamber and at least one process module.
